(19) United States
(12) Patent Application Publication
(10) Pub. No.: US 2021/0190873 A1
(43) Pub. Date: Jun. 24, 2021

(54) AUTOMATED BATTERY RECONDITIONING CONTROL SYSTEM

(71) Applicants: John P. Jadwinski, Avon, IN (US); David M. Milan, Munster, IN (US)

(72) Inventors: John P. Jadwinski, Avon, IN (US); David M. Milan, Munster, IN (US)

(21) Appl. No.: 16/360,712

(22) Filed: Mar. 21, 2019

Related U.S. Application Data
(60) Provisional application No. 62/646,098, filed on Mar. 21, 2018.

(51) Int. Cl. G01R 31/3835; G05B 15/02; G01R 31/396; G01R 31/371; H02J 7/00

(52) U.S. Cl. CPC G01R 31/3835; G05B 15/02; H02J 7/0013; G01R 31/371; H02J 7/0047; G01R 31/396

(57) ABSTRACT

An automated battery testing control system comprising a process controller, an analog controller, a relay controller, and a data processing system. The system may further comprise a charger and load bank controller, or a charger and a load bank itself. The data processing system is configured to record data from battery testing, store, retrieve data, and report data. The system may be used to test battery health and, if needed, identify battery cells eligible for use in a second use application.

### CROSS REFERENCE TO RELATED APPLICATIONS

This application claims priority to United States Provisional Patent Application No. 62/646098 filed 21 Mar. 2018 to the above-named inventors and is herein incorporated by reference in its entirety.

### FEDERALLY SPONSORED RESEARCH OR DEVELOPMENT

Not Applicable

### SEQUENCE LISTING, A TABLE, OR A COMPUTER PROGRAM

Not Applicable

### FIELD OF THE INVENTION

This invention relates generally to batteries, and more particularly to a control system and method for reconditioning batteries automatically. More particularly, it relates to an automated battery reconditioning control system that is well suited for use with lead acid batteries as they are removed from application.

### BACKGROUND

Energy storage applications using a battery typically utilize multiple battery cells that are removed and replaced at the end of their useful life. While consumer applications may rely on batteries that can only be used once, most industrial and commercial applications utilize batteries that can be recharged and reconditioned to return the battery to a useful state.

Traditionally, the method for analyzing and reconditioning used batteries involves connecting an entire battery bank of cells to an electrical cycler that will charge and discharge the cells many times. By checking the voltage of each of the cells during the charge and discharge cycles, the operator can determine which cells need to be removed because they have completely lost their ability to be reconditioned. Other cells that are still useful must then go through a de-sulfating process to return the lead acid plates to as close to original condition as possible.

In the current state-of-the-art process, the batteries under test require a trained operator to be present. And although a six-hour test will not occupy six hours of the operator's time, the operator must be present for the test to be running. Since the test runs with a very manually attentive aspect, batteries typically cannot be run overnight or on the weekends by themselves since they require constant supervision using traditional methods. In some instances, while a six-hour test is required to provide reliable data, some battery test facilities alter their process without notice and rely on a shorter four-hour test.

One problem in the current approach is that current automated battery discharge testers stop a discharge test once a cell drops below 1V. Using the traditional approach, operators measure voltage on an hourly basis, typically over the course of a six-hour test. However, if a given cell has a problem during the intervening time between operator measurements of the test—potentially as quickly as a minute after the last check—the cell voltage level will be reduced below a 1V safe level until the operator performs the normally scheduled measurement, notes the issue, stops the load, jumps the cell out (i.e. removes it from the test) manually, and restarts the test.

To do a detailed test, the operator must be well trained and have experience watching for certain conditions. The resources required to train a battery technician to perform the testing and analysis needed is a time-consuming process; further, relying on battery technicians to perform testing and analysis introduces risk of error and jeopardizes quality control since traditional methods are highly dependent on manual focus and attention span. One problem inherent in this approach, then, is that a battery discharge test is not consistent from operator to operator or from day to day.

In addition, if a fleet of batteries towards the end of their useful life are in question, it is typically not cost-effective to perform a six-hour load test on a fleet of battery vehicles or devices (e.g., forklifts or lift gates). This is because the process will commonly result in wasted time by jumping out more bad cells than there are good cells in each battery test, and each step of the manual process requires the operator entering each cell's performance data and plotting curves, and then interpreting the data from the fleet to determine which of the cells are eligible for reconditioning and, therefore, reuse.

Additionally, the process of analyzing battery cells is an inefficient allocation of human resources. Measuring individual cell voltages can effectively be done by one person, as it is literally a 2-handed operation to measure the voltage of one cell. The operator measures one cell, physically puts down the electrical leads, picks up the clip board and pen and writes the value down or enters the values into an electronic device. The process will repeat itself 12, 18, 24, 36, or 48 times to get an accurate reading, every hour on the hour for six consecutive hours using traditionally accepted test methodology. It is easier and quicker to have one person read the volt meter and another person enter the values into a spreadsheet, but then the process requires two operators and the efficiencies gained still require over half the time for the process to play out.

At the conclusion of the testing, another problem is that the operator must disconnect the battery that has just been tested from a load bank and connect another battery to the load bank manually. This also means that if an operator wants to stop a discharge test because the battery temperature has increased beyond a predefined safe limit, switch the load bank to another battery to perform a discharge test as the temperature drops, then switch back to the first battery to continue the test when the second battery completes a test or the temperature of the second battery increases beyond a predefined safe limit, the operator has to be in attendance of the test at each occurrence.

In practical terms, one of the simple issues presented by manually entered data is the legibility of hand-written load test results or the likelihood of transposing numerals incorrectly in electronic recording processes.

Moreover, putting multiple cycles on a battery to equalize the cells or to de-sulfate the lead plates is not a cost-effective option on an aging battery fleet because it is a labor-intensive process.

Furthermore, many owners of many batteries would greatly appreciate the data that could be gleaned from performing load tests on their fleet of batteries at the end of the year or other given interval. This information could help understand the status of their battery fleet, predict maintenance requirements, and predict capital requirements of the company for purchases of new equipment over the following years using the real data of the actual batteries in the fleet as opposed to historic trends.

Therefore, there exists a pronounced need in the marketplace to develop an automated reconditioning control system that reduces the amount of human manipulation of battery cells during the testing and evaluation process, automatically transitions batteries and load banks to more efficiently utilize time, automatically monitors the health of the battery cells to indicate when cells have exceeded a safe temperature or dropped below a safe voltage level, and accurately records and reports the data from the tests.

### BRIEF SUMMARY OF THE INVENTION

The present disclosure is most generally related to an automated battery testing control system configured to automatically test, evaluate, and condition a set of lead acid batteries.

The control system of the present disclosure is configured to automatically test, evaluate, and condition at least one set of lead acid batteries by generally directing, controlling, and manipulating a series of additional controllers and systems, including, but not limited to, a process controller, an analog controller, a relay controller, and a data processing system.

In another aspect, the present disclosure is related to a method for automatically testing a first set of lead acid battery cells comprising at least one of the steps of: managing and directing an analog controller, a relay controller, and a data processing system through the use of a process controller; testing the set lead acid battery cells; and removing an individual cell from the testing if the individual cell falls below a pre-set voltage threshold or exceeds a preset temperature threshold.

### BRIEF DESCRIPTION OF THE DRAWINGS

The accompanying drawings are included to provide a further understanding of the present invention and are incorporated in and constitute a part of this specification. The drawings illustrate exemplary embodiments of the present invention and together with the description serve to further explain the principles of the invention. Other aspects of the invention and the advantages of the invention will be better appreciated as they become better understood by reference to the Detailed Description when considered in conjunction with the accompanying drawings, and wherein:

FIG. 1 is a block diagram of an exemplary embodiment of the system, according to the present disclosure; and

FIG. 2 is a diagram of an apparatus utilizing the system, according to the present disclosure.

### DETAILED DESCRIPTION OF THE INVENTION

The following detailed description includes references to the accompanying drawings, which forms a part of the detailed description. The drawings show, by way of illustration, specific embodiments in which the invention may be practiced. These embodiments, which are also referred to herein as “examples,” are described in enough detail to enable those skilled in the art to practice the invention. The embodiments may be combined, other embodiments may be utilized, or structural, and logical changes may be made without departing from the scope of the present invention. The following detailed description is, therefore, not to be taken in a limiting sense.

Before the present invention is described in such detail, however, it is to be understood that this invention is not limited to particular variations set forth and may, of course, vary. Various changes may be made to the invention described and equivalents may be substituted without departing from the true spirit and scope of the invention. In addition, many modifications may be made to adapt a particular situation, material, composition of matter, process, process act(s) or step(s), to the objective(s), spirit or scope of the present invention. All such modifications are intended to be within the scope of the disclosure made herein.

Unless otherwise indicated, the words and phrases presented in this document have their ordinary meanings to one of skill in the art. Such ordinary meanings can be obtained by reference to their use in the art and by reference to general and scientific dictionaries.

References in the specification to “one embodiment” indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The following explanations of certain terms are meant to be illustrative rather than exhaustive. These terms have their ordinary meanings given by usage in the art and in addition include the following explanations.

As used herein, the term “and/or” refers to any one of the items, any combination of the items, or all of the items with which this term is associated.

As used herein, the singular forms “a,” “an,” and “the” include plural reference unless the context clearly dictates otherwise.

As used herein, the terms “include,” “for example,” “such as,” and the like are used illustratively and are not intended to limit the present invention.

As used herein, the terms “preferred” and “preferably” refer to embodiments of the invention that may afford certain benefits, under certain circumstances. However, other embodiments may also be preferred, under the same or other circumstances.

Furthermore, the recitation of one or more preferred embodiments does not imply that other embodiments are not useful and is not intended to exclude other embodiments from the scope of the invention.

As used herein, the terms “front,” “back,” “rear,” “upper,” “lower,” “right,” and “left” in this description are merely used to identify the various elements as they are oriented in the FIGS, with “front,” “back,” and “rear” being relative to the apparatus. These terms are not meant to limit the elements that they describe, as the various elements may be oriented differently in various applications.

As used herein, the term “coupled” means the joining of two members directly or indirectly to one another. Such joining may be stationary in nature or movable in nature. Such joining may be achieved with the two members or the two members and any additional intermediate members being integrally formed as a single unitary body with one another or with the two members or the two members and any additional intermediate members being attached to one another. Such joining may be permanent in nature or alternatively may be removable or releasable in nature. Such joining may allow for the transfer of fluids, gasses, and plasma or the flow of electricity or electrical signals.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element without departing from the teachings of the disclosure.

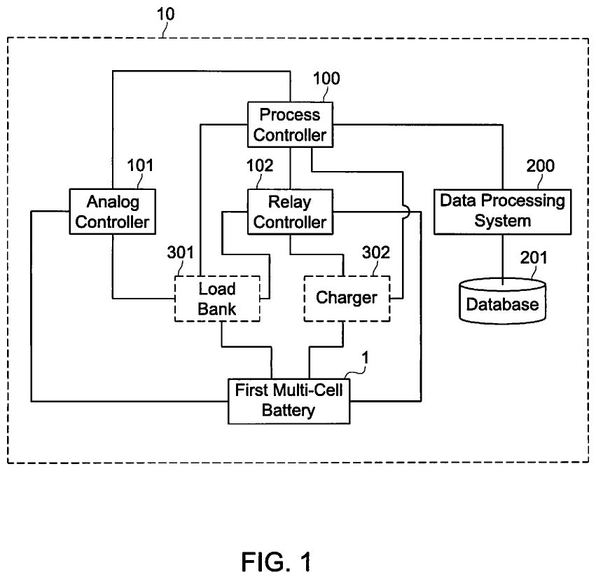

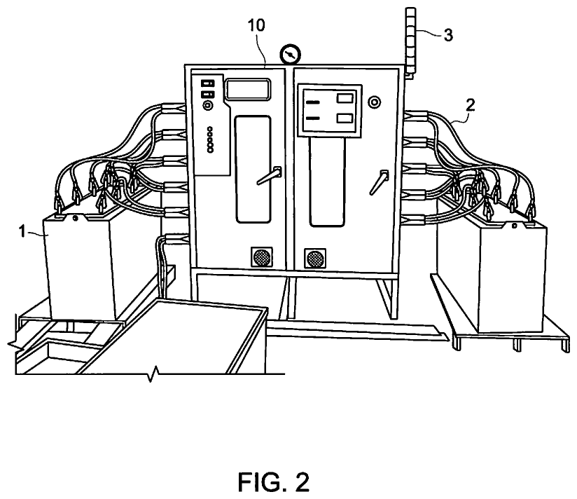

Referring now to FIGS. 1-2 of the automated battery reconditioning control system of the present disclosure, an automated battery control system 10 (the “control system 10”) is depicted. The control system 10 is generally and exemplarily used to automate, evaluate, and recondition lead acid batteries 1. The control system 10 comprising a process controller 100, an analog controller 101, a relay controller 102, and a data processing system 200.

The control system 10 may be used, for example, to automate the test, evaluation, and reconditioning process of lead acid batteries 1. Specifically, the control system 10 optionally comprises the necessary hardware to perform the typical battery discharge, charge, and reconditioning (i.e., de-sulfation) processes of lead acid batteries 1, such as a load bank 301 or charger 302. Alternatively, control system 10 may be configured to interface with existing load banks 301 or chargers 302 so long as the incumbent system(s) have an interface control feature. The control system 10 further includes additional hardware and software that automates the processes and additionally performs automated data entry, data retrieval, data presentation, production of data reports, and data storage for use in testing and analyzing a lead acid battery coupled to the control system 10.

The process controller 100 controls the interactions between the analog controller 101, relay controller 102, load bank 301, and optional charger 302 to perform multiple functions on multi-cell lead acid batteries 1. Further, the process controller is configured for a coupling in an interaction with the data processing system 200 to receive and provide battery test information to a user of the control system 10.

The data processing system 200 is configured and enabled to facilitate the processing of data and lead acid battery 1 test information outside of direct interaction with batteries 1. The data processing system 200 further configured to facilitate interactions with the process controller 100 and at least a single database 201 or databases 201 to generally store, collect, and retrieve battery 1 related information for pre- and post-processing of battery 1 information and information for a given fleet of batteries 1.

In use, as it relates to an application of the control system 10 to a predetermined coupling of lead acid battery cells 1, such as a 12-cell lead acid battery system 1, the disclosure of the present invention controls the discharge and charge of the battery 1 system continuously. By doing so, the testing is allowed to continue to proceed even when the voltage of a cell or multiple cells of the battery 1 system are near, at, or below the level at which further discharge or charge cycles of the battery 1 system cannot be maintained. Specifically, the control system 10 is configured to create a short circuit around some individual, weak, or dead and damaged cells, thereby automatically bypassing the damaged cell of the battery 1 system from discharge or charge cycling.

In known methods, the process of load testing a given battery within a battery system through various discharge/charge cycles to obtain the required data that correlates to the given battery and overall battery system's health is a labor intensive and manual process. The control system 10 of the present disclosure automates the entire discharge/charge process through a predetermined testing protocol over any appropriate test duration, such as longer than about a three (3) hour test, longer than about a four (4) hour test, or longer than about a five (5) hour test, or longer than about a six (6) hour test.

During this testing, the control system 10 monitors individual cells within the battery 1 system coupled to the control system 10, collecting individual battery 1 cell data and providing output to the user that may include, but not be limited to, a graphic representation of the results. In contrast to known test methods and systems, the control system 10 and its coupled controllers and systems does not cease operation if a “bad” cell is indicated during the test process, thereby preventing the stoppage of the entire testing sequence. To this end, the control system 10 is configured to allow for individual battery 1 cells that are being tested to be bypassed during the testing process allowing the entire testing process to continue through completion. Maintaining the test process is a result of the modified hardware structure and elements of the control system 10. Specifically, the control system 10 comprises built in contactors 2 that will “jump-out” individual cells of the battery 1 system automatically if they fall below specific voltage level, thus enabling a continuous testing process.

Additionally, the control system 10 includes a customizable charging system that may result in cycling the battery to balance out any imbalance between battery cells in a given set of cells. Accordingly, the control system 10 collects all test data and cell readings in the data processing system 200 and graphs the results of each cell of the coupled battery 1 system. By automating the data collection, the control system 10 of the present disclosure solves the problem of unreliable data from a manual battery discharge test. That is, in a manual battery test project, the operator may inadvertently introduce inaccurate data by transcription errors or collecting insufficient data points. The automated control system 10 of the present disclosure may be customized by the user to collect data points as often as, e.g., every 60 seconds, every 10 seconds, every 1 second, every 0.1 seconds, every 0.01 seconds, or even more frequently by using system 10 features to enable automation of the voltage data collection and recordation.

The software of the control system 10 further comprises a feature that permits analysis on a cellular level for batteries 1. Such data identifies cellular matches, which allows for the creation of “good” battery 1 systems from the assemblage of deteriorated, aged battery cells that can be matched and assembled into an overall secondary-use battery 1 system.

The control system 10 is configured such that the system 10 can operate continuously, including outside of traditional business hours, automatically and without user interaction.

The control system 10 comprises a reporting system within the data processing system 200 that includes software configured to receive the data of the battery 1 cells under test. The data is compiled by the software to provide information at the individual cell level to the user, including a summary of the data numerically and graphically and shown in customizable formats. As such, data may be collated according to specific identifying information, such as, but not limited to customer and fleet information.

Advantageously, this reduces the risk of error inherent in the traditional methods of recording data in handwritten notes. Further, the control system 10 eliminates the risk of error for under-trained or incorrectly trained operating personnel, as well as the potential for inconsistencies between individual operators.

### APPLICATION OF THE INVENTION

The control system 10 of the present disclosure automates battery discharge and charge processes for a multi-cell battery 1 coupled to the system 10. The control system 10 is configured to bypass cells of the multi-cell battery when the individual cell falls below the predetermined discharge conditions of the cell. Cells can also be bypassed for the charge process. In contrast, current battery test system technology stops the discharge process and requires manual override by an operator to continue battery analysis of a battery 1 coupled to the system 10, resulting in delays in the battery review process.

Advantageously, as a first battery string coupled to the system 10 is being tested and is in the discharge process, a second battery string additionally coupled to the system 10 can be prepared to be tested. The preparation of the second battery string allows for unattended continuation of the testing process. For example, the control system 10 is able to switch between the coupled battery string or cell from discharge to charge and from a standing or a rest condition to discharge. In such a use case, if the first coupled battery string or cells within the string encounter test conditions that prevent the discharge of a battery cell or string, the control system 10 may be configured to switch to the second coupled battery string. If conditions with the first coupled battery string are normalized and the second coupled battery string has completed the discharge process or has entered a condition that prevents it from continuing the process, the control system 10 may be configured to switch back to the first battery string.

In another aspect, after a discharge test has been successful, the system 0 can charge said battery after testing up to capacity for immediate use.

In a related aspect, the control system 10 may be used to recondition cells via de-sulfation, which may be accomplished by briefly repeated charge/cool/discharge/cool cycles within a coupled battery 1 system. For example, coupled battery 1 cells may undergo at least 1 such cycle (or at least 2 cycles, or at least 3 cycles, or at least 4 cycles, or at least 5 cycles) in, e.g., less than about 4 days, less than about 3 days, less than about 2 days, less than about 1 day, less than about 12 hours, less than about 6 hours, less than about 4 hours, less than about 2 hours, less than about 1 hour, less than about 30 minutes, less than about 10 minutes, less than about 5 minutes, or less than about 1 minute in order to recondition the coupled batteries 1.

The control system 10 is configured to efficiently execute the discharge/charge process while providing more accurate data, automated reports, and more timely evaluation of the coupled battery 1 through use of the data processing system 200. The results of the testing may be stored in the database 201 for subsequent analysis of and comparison of a given cell's performance over time to better determine the appropriate uses of the cell throughout its lifecycle. For example, the automated processes of the control system 10 may be used by a fleet owner on an annual basis to assess the health and performance of the fleet batteries to better predict the capital expenditure needs for new equipment prospectively according to the predicted end of life.

Further, the data collected by the data processing system 200 during an individual battery 1 test can be correlated to a plurality of stack lights 3 to visually indicate to the user the progress of a given test. The collected data may also be directly communicated to the user via remote monitoring methods, including, but not limited to, mobile phone apps, text messaging, or emails.

The software of control system 10 may also be configured to integrate with third party systems, such as, but not limited to, load banks, chargers, smart battery devices, and other test equipment.

In one optional application, the control system 10 may be configured for identification of battery cells that may be removed from the coupled battery 1 system to function as donor cell(s) for re-use in a new second-use battery system.

This application is intended to cover adaptations or variations of the present subject matter. It is to be understood that the above description is intended to be illustrative, and not restrictive. The scope of the present subject matter should be determined with reference to the appended claims, along with the full scope of legal equivalents to which such claims are entitled.

What is claimed is:

1. An automated testing control system for a multi-cell battery, the testing control system configured for removable receipt of the multi-cell battery in a coupling, the testing control system comprising:
a process controller;
an analog controller, the analog controller coupled to the process controller and the multi-cell battery;
a relay controller, the relay controller coupled to the process controller and the multi-cell battery; and
a data processing system, the data processing system coupled to the process controller and configured to record data collected from the multi-cell battery.

2. The automated battery testing control system of claim 1, further comprising a charger and load bank controller.

3. The automated battery testing control system of claim 1, further comprising a customizable charging system including a charger and a load bank.

4. The automated battery testing control system of claim 1, wherein the data processing system is configured to record data from battery testing, store, retrieve data, and report data.

5. The automated battery testing control system of claim 1, wherein the process controller is configured to control the analog controller and the relay controller.

6. The automated battery testing control system of claim 3, wherein the process controller is configured to control the analog controller, the relay controller, the load bank, and the charger.

7. The automated battery testing control system of claim 1, wherein the data processing system facilitates interaction with the process controller and a database to store, collect, and retrieve data.

8. The automated battery testing control system of claim 1, wherein the relay controller comprises contactors configured to bypass individual cells of the multi-cell battery if the individual cells fall below a specified and predetermined voltage threshold.

9. The automated battery testing control system of claim 1, wherein the data processing system collects data points every 60 seconds.

10. A method for automatically testing a first set of lead acid battery cells comprising:
managing an analog controller, a relay controller, and a data processing system using a process controller;
testing the set lead acid battery cells;
removing an individual cell of the first set of lead acid battery cells from the testing if the individual cell falls below a predetermined voltage threshold or exceeds a preset temperature threshold.

11. The method of claim 10 further including preparing a second set of lead acid battery cells for testing during the testing of the first set of lead acid battery cells.

12. The method of claim 10 further including charging the first set of lead acid battery cells to capacity for immediate use.

13. The method of claim 10 further including repeated cycling of charging and discharging over at least about 20 cycles within less than about 10 minutes.

14. The method of claim 10 wherein the at least about 20 cycles is repeated within less than about 5 minutes.

15. The method of claim 10 wherein the at least about 20 cycles is repeated within less than about 2 minutes.

16. The method of claim 10 further including communicating data collected during the testing via a mobile phone application, text messaging, or emails.

17. The method of claim 10 further including identification of an individual battery cell within the first set of lead acid battery cells that may be re-used in a second use battery system.
